(19) United States
(12) Patent Application Publication
(10) Pub. No.: US 2017/0320453 A1
(43) Pub. Date: Nov. 9, 2017

(54) RELAY CONTROL BOX ASSEMBLY

(71) Applicant: FORD GLOBAL TECHNOLOGIES, LLC, Dearborn, MI (US)

(72) Inventor: Kyaw Kyaw SOE, Billericay Essex (GB)

(73) Assignee: FORD GLOBAL TECHNOLOGIES, LLC, Dearborn, MI (US)

(21) Appl. No.: 15/586,027

(22) Filed: May 3, 2017

(30) Foreign Application Priority Data
May 4, 2016 (GB) 1607774.5

(51) Int. Cl. B60R 16/023; B60R 16/03; H05K 5/00; H05K 7/14

(52) U.S. Cl. CPC B60R 16/0239; H05K 7/1427; B60R 16/0315; H05K 5/0017

(57) ABSTRACT

An electrical system for a vehicle is provided. The electrical system includes a control unit configured to control operation of one or more vehicle systems. The electrical system also includes a multiplexed data bus communicatively coupled to the control unit, and configured to carry multiplexed signals to and from the control unit. The electrical system also includes a relay control box. The relay control box has one or more relays, and a controller. The controller is communicatively coupled to the multiplexed data bus, and is configured to decode the multiplexed control signals from the control unit to generate one or more decoded signals, and operate the one or more relays according to the decoded signal. A method of retrofitting a motor vehicle relay control box assembly is also provided.

### CROSS-REFERENCE TO RELATED APPLICATIONS

This application claims foreign priority benefits under 35 U.S.C. §119(a)-(d) to GB Application 1607774.5, filed May 4, 2016, which is hereby incorporated by reference in its entirety.

### TECHNICAL FIELD

The present disclosure relates to an electrical system for a motor vehicle configured to reduce an amount of wiring between electronic control units and a relay control box provided within the electrical system.

### BACKGROUND

Motor vehicles often comprise a relay control box in which one or more relays are provided. The relays are configured to allow electrical devices provided on the vehicle to be switched on and off, often using a lower current or voltage than that required to drive the electrical device.

Each relay typically requires one or more connections to provide the necessary control signals to the relay. Hence, the relay control box typically comprises one or more inputs for each relay provided in the relay control box.

The operation of each of the relays is typically controlled by an Electronic Control Unit (hereinafter “ECU”) and hence, it may be necessary for one or more wires to be provided between each relay and the relevant ECU. One or more of the relays may be controlled by a different ECU to one or more of the other relays. In some arrangements, each of the relays may be controlled by a different ECU. The wiring of the relay control box connecting each of the relays to the relevant ECU may be highly complicated and require large lengths of wire routed to various different location on the vehicle, e.g. where the ECUs are provided.

With reference to FIG. 1, a previously proposed electrical system 2 for a motor vehicle typically comprises a battery 4, one or more ECUs, such as a Powertrain Control Module (hereinafter “PCM”) 6 and one or more Body Control Units (hereinafter “BCU”s), such as a first BCU 8a and a second BCU 8b. The electrical system further comprises a relay control box assembly 12.

In the electrical system 2 depicted in FIG. 1, the relay control box 12 comprises first and second relays 12a, 12b. The first relay 12a is configured to control the supply of power to a starter motor 14 of the vehicle and the second relay 12b is configured to control the supply of power to headlights 16 of the vehicle.

As shown in FIG. 1, the operation of the first relay 12a is controlled by the PCM 6 and the operation of the second relay 12b is controlled by the second BCU 8b. As mentioned above, each relay is typically connected to one or more signal wires for the operation of the relay to be controlled. Accordingly, in the electrical system 2 shown in FIG. 1, two signal wires 18a, 18b are provided between the PCM 6 and the relay control box assembly 12 and two further signal wires 20a, 20b are provided between the second BCU 8b and the relay control box 12.

The relay control box 12 is configured to facilitate a connection between the two signal wires 18a, 18b and the two further signal wires 20a, 20b with the first and second relays 12a, 12b, respectively. For example, as shown in FIG. 1, the relay control box 12 may be configured to allow the signal wires 18a, 18b, 20a, 20b to pass into a housing of the relay control box 12, and connect to the first and second relays 12a, 12b, directly.

During production of the vehicle, it may become desirable to install a third relay (not shown) with the vehicle electrical system 2. For example, the third relay may be configured to control the supply of power to an air conditioning system (not shown) of the vehicle. The air conditioning system may be controlled by the second BCU 8b, and, hence, it may be desirable for the operation of the third relay to be controlled by the BCU 8b. It may, therefore, be desirable for two additional signal wires (not shown) to be provided, and routed through the vehicle from the second BCU 8b to the relay control box 12 in order to provide control signals to the third relay.

Furthermore, as mentioned above, the relay control box 12 is configured to facilitate connections between the signal wires 18a, 18b, 20a, 20b, and the first and second relays 12a, 12b. If the relay control box 12 comprises a third relay, it may be necessary for the relay control box to facilitate additional connections between the additional signal wires and the third relay. However, in some arrangements, the relay control box 12 may not be able to facilitate any additional connections. Hence, in order to provide the third relay within the vehicle electrical system 2, it may be necessary to provide an additional relay control box (not shown), or replace the relay control box 12 with an alternative relay control box that is capable of facilitating additional connections.

Additionally or alternatively, at another point during the vehicle production process, it may become desirable to reconfigure the software provided on the first and/or second BCUs 8a, 8b. For example, it may be desirable to reconfigure the software such that the first BCU 8a is configured to determine when the head lights 16 of the vehicle should be switched on. Hence, it may be desirable for the first BCU 8a to control the operation of the second relay 12b. If the vehicle is provided with the electrical system 2 comprising the relay control box 12, it may be necessary to re-wire the electrical system 2 such that the further signal wires 20a, 20b are provided between the first BCU 8a and the relay control box 12.

In the arrangement shown in FIG. 1, the wiring provided between the PCM 6 and the relay control box assembly 12 is similar to the wiring provided between the second BCU 8b and the relay control box assembly. However, in some arrangements, the wiring provided between a particular ECU and the relay control box assembly may be specific to the ECU being used. Additionally or alternatively, wiring provided within the relay control box assembly 12 to facilitate connections between the signal wires and the first and second relays 12a, 12b may be specific to the ECU being used. Hence, if it is desirable to change the ECU used to control the operation of the first and/or second relay 12a, 12b, it may be necessary to reconfigure the relay control box assembly 12, e.g. to enable the desired connections to be facilitated.

Implementing such hardware changes and/or rewiring can be expensive and add significant amounts of time to the production schedule of the motor vehicle. It is, therefore, desirable to provide an electrical system that is flexible as to the number, and arrangement of relays provided within the electrical system and the ECU configured to control each of the relays.

### SUMMARY

According to an aspect of the present disclosure, there is provided an electrical system for a motor vehicle, the system includes an Electronic Control Unit (ECU) of the vehicle. The ECU is configured to control the operation of one or more systems on the vehicle. The system also includes a multiplexed data bus communicatively coupled to the ECU, and configured to carry multiplexed control signals to and from the ECU. The system further includes a motor vehicle relay control box assembly having a housing, one or more relays, and a controller. The controller is communicatively coupled to the multiplexed data bus. The controller is configured to decode the multiplexed control signals from the ECU to generate one or more decoded control signals, and control the operation of the one or more relays according to the decoded control signal. The controller and the one or more relays are provided within the housing. The housing defines a housing space configured to receive one or more additional relays.

The controller may comprise one or more modules configured to decode the multiplexed control signals, e.g. to generate one or more decoded control signals; process the one or more decoded control signal to generate one or more relay control signals; and drive the one or more relays according to the relay control signals. In other words, the controller may comprise a decoder module, a processor module and/or a relay driver module.

The relay control box assembly may comprise a relay driver module configured to drive the one or more relays according to the decoded control signal, e.g. according to signals from the controller. The relay driver module may be a module of the controller.

The motor vehicle relay control box assembly may comprise a processor module configured to receive decoded control signals and generate one or more relay control signals. The processor module may be a module of the controller.

The processor module may be communicatively coupled to the relay driver module. The relay driver module may be configured to drive the one or more relays according to the relay control signals.

The relay control box assembly may comprise a decoder module configured to decode the multiplexed control signal. The decoder module may be a module of the controller. At least two of the processor module, the relay driver module and the decoder module may be combined within a single component, e.g. chip, or each of the modules may be a separate component.

The motor vehicle relay control box assembly may comprise a further housing.

The further housing may comprise one or more relays provided within the housing. Additionally or alternatively, the further housing may comprise a housing space, configured to receive one or more additional relays.

The relay control box assembly may further comprise a circuit board. The one or more relays may be mounted on the circuit board. The controller or one or more modules of the controller may also be mounted on the circuit board. The circuit board may further define a circuit board space configured to allow one or more additional relays to be mounted on the circuit board. The circuit board space may correspond to the housing space, e.g. such that an additional relay mounted to the circuit board in the circuit board space may be housed within the housing space.

The circuit board space may be configured such that each of the additional relays can be either an electromechanical relay or a transistor relay such as a power transistor, e.g. a FET (“Field Effect Transistor”). At least one of the relays may be an electromechanical relay. Additionally or alternatively, at least one of the relays may be a transistor relay. Electromechanical relays and transistor relays are provided within this specification as examples of electrical switches. However, it is envisaged that any desirable switches may be provided within the relay control box assembly in any desired combination.

The electrical system may further comprise one or more additional ECUs. The additional ECUs may be communicatively coupled to the multiplexed data bus. The controller may be configured to receive multiplexed control signals from the additional ECUs.

According to another aspect of the present disclosure, there is provided a motor vehicle relay control box assembly includes an input, a controller, one or more relays, and a housing. The input is configured to receive a multiplexed control signal from one or more ECUs. The controller is configured to decode the multiplexed control signal. Operation of the one or more relays is controlled according to the multiplexed control signal. The housing, wherein the controller and the one or more relays are provided within the housing, defines a housing space configured to receive one or more additional relays.

The relay control box assembly may further comprise a further housing. One or more relays may be provided within the further housing. Additionally or alternatively, one or more housing spaces may be provided within the further housing.

The relay control box assembly may further comprise a circuit board. The one or more relays may be mounted to the circuit board. The circuit board may define a circuit board space configured to receive one or more additional relays, such that the additional relays may be mounted on the circuit board.

The motor vehicle relay control box assembly may be configured for use within the electrical system according to a previously mentioned aspect of the disclosure.

According to another aspect of the disclosure, there is provided a method of retrofitting a motor vehicle relay control box assembly. The method includes providing a relay control box assembly. The control box assembly includes an input, a controller, one or more relays, and a housing. The controller is communicatively coupled to the input and configured to decode multiplexed control signals received at the input. The one or more relays is communicatively coupled to the controller. The operation of the one or more relays is controllable according to the multiplexed control signals. The housing, wherein the controller and the one or more relays are provided within the housing, defines a housing space configured to receive one or more additional relays. The method further includes coupling the input of the relay control box assembly to a multiplexed data bus of the vehicle. The multiplexed data bus is communicatively coupled to one or more ECUs of the vehicle.

The method may further comprise reconfiguring one or more of the ECUs to transmit control signals to the relay control box assembly via the multiplexed data bus.

According to another aspect of the present disclosure, there is provided a method of upgrading a motor vehicle relay control box assembly, The relay control box assembly includes a controller, one or more relays, and a housing. The controller is communicatively coupled to a multiplexed data bus of the vehicle and is configured to decode multiplexed control signals from one or more ECUs of the vehicle. The one or more relays is communicatively coupled to the controller. The operation of the one or more relays is controllable according to the multiplexed control signals. The housing, wherein the controller and the one or more relays are provided within the housing, defines a housing space configured to receive one or more additional relays. The method further includes providing the one or more additional relays, and communicatively coupling the one or more additional relays to the controller.

The method may further comprise reconfiguring the controller to control the operation of the one or more additional relays according to the multiplexed control signals.

Additionally or alternatively, the method may further comprise reconfiguring one or more of the ECUs to transmit multiplexed control signals via the multiplexed data bus to control the operation of the additional relays.

To avoid unnecessary duplication of effort and repetition of text in the specification, certain features are described in relation to only one or several aspects or embodiments of the invention. However, it is to be understood that, where it is technically possible, features described in relation to any aspect or embodiment of the invention may also be used with any other aspect or embodiment of the invention within the scope of the claims.

For a better understanding of the present invention, and to show more clearly how it may be carried into effect, reference will now be made, by way of example, to the accompanying drawings, in which:

### BRIEF DESCRIPTION OF THE DRAWINGS

FIG. 1 is a schematic view of a previously proposed electrical system for a motor vehicle;

FIGS. 2A and 2B are schematic views of relay control box assemblies according to arrangements of the present disclosure;

FIG. 3 is a schematic view of an electrical system for a motor vehicle according to arrangements of the present disclosure;

FIG. 4 shows a method of retrofitting a relay control box assembly according to arrangements of the present disclosure; and

FIG. 5 shows a method of upgrading a relay control box assembly according to arrangements of the present disclosure.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

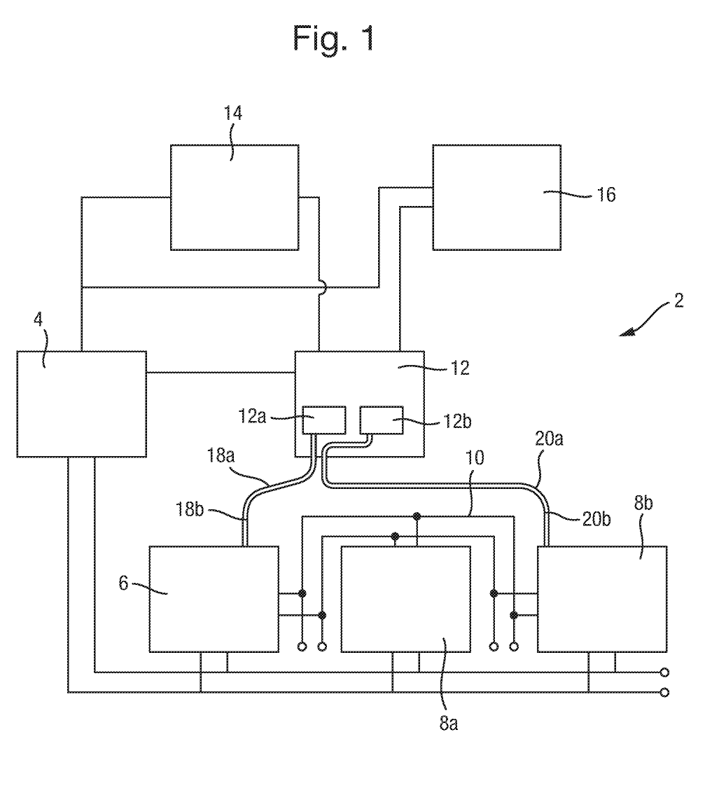

As shown in FIG. 1, each of the ECUs (6, 8a, 8b) may be communicatively coupled to a data bus 10, e.g. a multiplex data bus, such as a Controller Area Network (hereinafter “CAN”) data bus, provided on the vehicle. The PCM 6, and the first and second BCUs 8a, 8b may be configured to communicate with each other by passing messages over the data bus 10. Messages transmitted via the data bus 10 may be received by each of the other ECUs, and any other devices communicatively coupled to the data bus 10, regardless of which ECU is sending the message and which ECU or other device the message is intended.

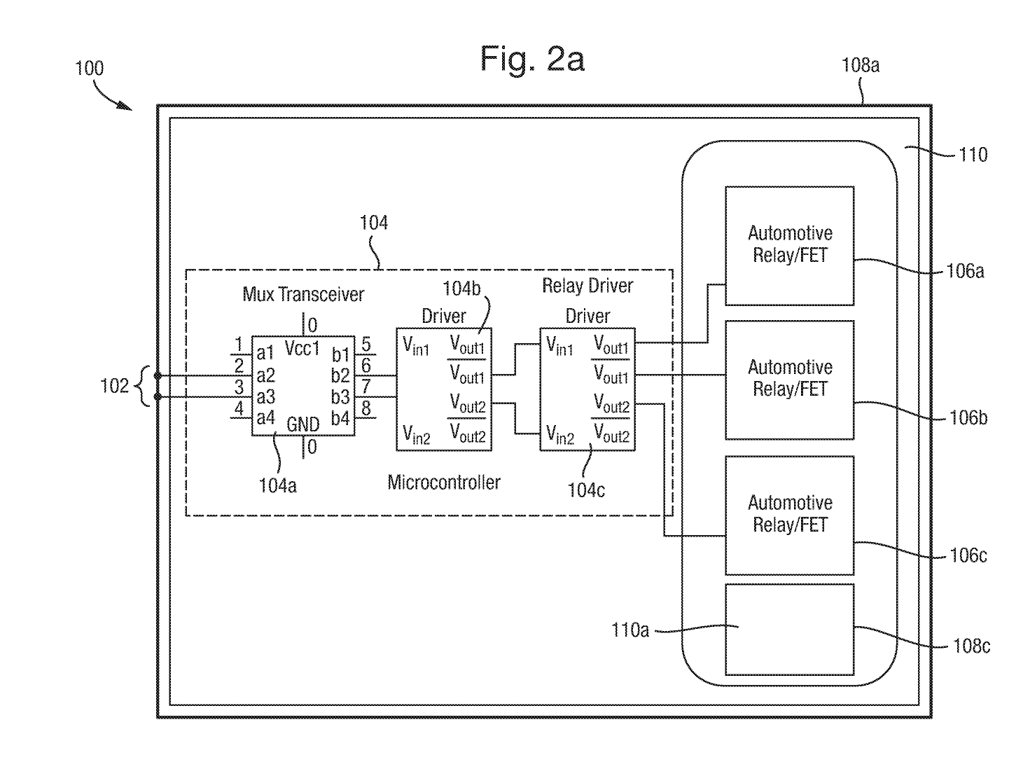

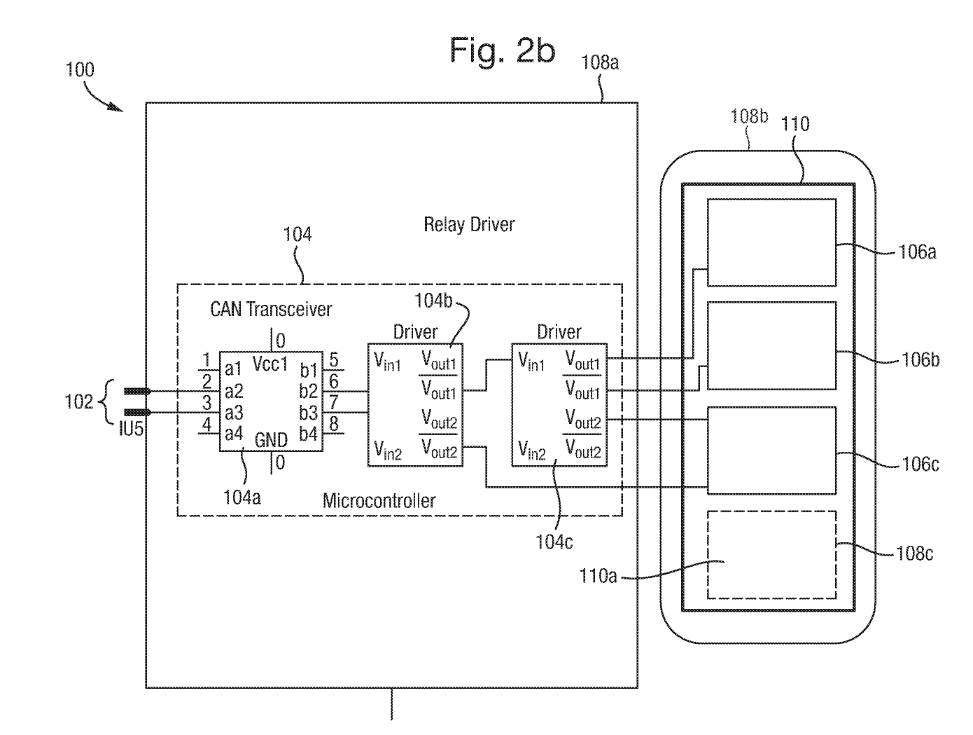

With reference to FIGS. 2A and 2B, a relay control box assembly 100, according to arrangements of the present disclosure, may be configured to communicate with the PCM and/or the BCUs 8a, 8b via the data bus 10. The relay control box assembly 100 comprises an input 102, a controller 104 communicatively coupled to the input 102, and one or more relays 106a, 106b, 106c.

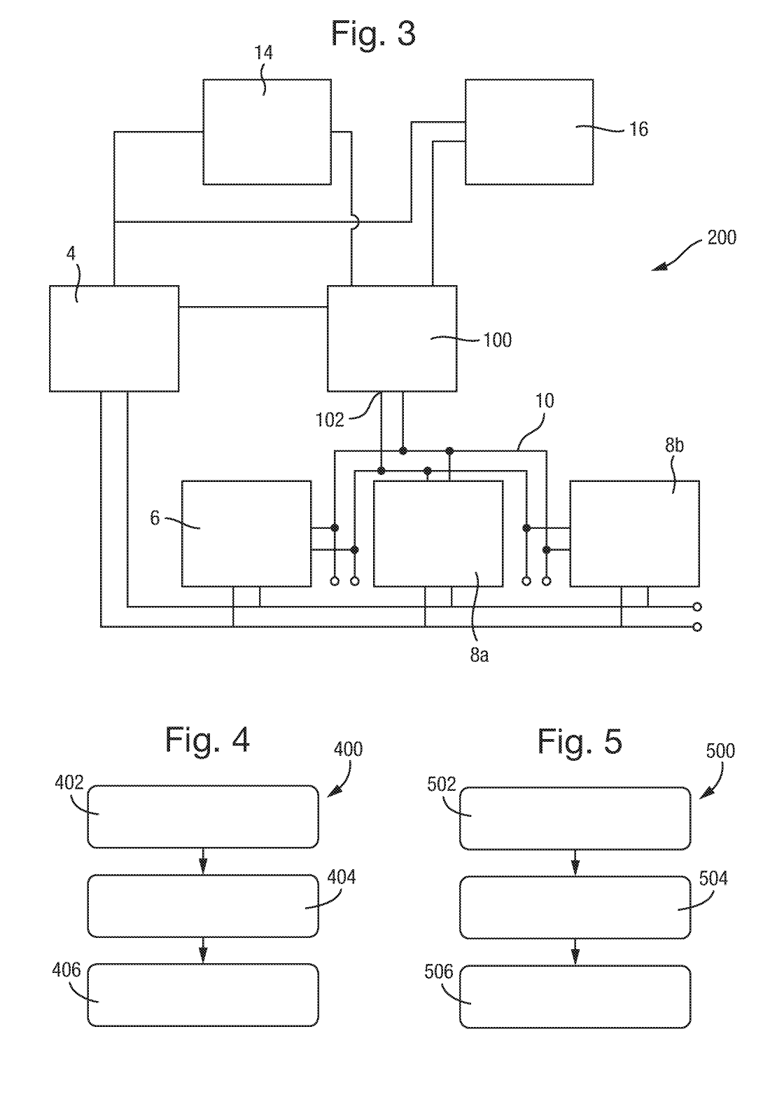

With reference to FIG. 3, an electrical system 200 for a motor vehicle functions in a similar way to the electrical system 2 described above. As shown in FIG. 3, the relay control box assembly 100 may be coupled to the data bus 10 at the input 102.

As shown in FIGS. 2A and 2B, the controller 104 may comprise one or more modules, such as a transceiver and/or decoder module 104a, a processor module 104b and a relay driver module 104c. In alternative arrangements (not shown), one or more of the modules may be omitted, as described below. Additionally or alternatively, in some arrangements, two or more of the modules may be combined, e.g. into a single module configured to perform the functions of each module.

The decoder module 104a may be configured to receive multiplexed signals transmitted on the data bus 10. The decoder module 104a may decode the multiplexed signals in order to generate one or more decoded control signals.

As mentioned above, the decoder module 104a may receive each of the multiplexed signals transmitted via the data bus 10. One or more of the multiplexed signals received by the decoder module 104a may not relate to the control of the relay control box assembly 100, e.g. to the control of the relays 106a-c provided within the relay control box assembly 100. The decoder module 104a may, therefore, be configured to determine whether a received multiplexed control signal relates to the control of the relay control box assembly 100, and may decode the multiplexed control signals that do relate to the control of the relay control box assembly 100. Alternatively, the decoder module may decode each of the multiplex control signals, but may only generate decoded control signals for the multiplexed control signals that relate to the control of the relay control box assembly 100.

The processor module 104b may receive the decoded control signals from the decoder 104a. The processor module 104b may control the operation of the relays according to the decoded control signals. For example, the processor mode 104b may process the decoded control signal to generate one or more relay control signals, and may transmit each relay control signal to the relay being controlled.

In some arrangements, the relays 106a-c provided in the relay control box assembly 100 may be electro-mechanical relays comprising an electromagnetic coil (not shown) configured to generate an electromagnetic field when an electric current is passed through the coil. The electromagnetic field may in turn act on a mechanical switch element (not shown) within the relay to switch the relay. In other arrangements, the relays 106a-c may be transistor relays comprising one or more power transistors, such as FETs. Any combination of electro-mechanical relays and transistors relays may be provided within the relay control box assembly 100.

The current output by the processor module 104b may be low and insufficient to control, e.g. directly control, the operation of the relays 106a-c. In other words, the current output by the processor module 104b may be too low to cause the coil to generate a sufficiently strong electromagnetic field to switch the mechanical switch element. Hence, it may be desirable for the relay control signals generated by the processor module 104b to be transmitted to the relay driver module 104c. The relay driver module 104c may comprise one or more driver circuits (not shown) configured to amplify the current output by the processor module 104b in order to control the operation of the relays 106a-c.

In the arrangement shown in FIG. 2b, the first and second relays 106a and 106b are electromechanical relays, and the third relay 106c is a semiconductor relay, e.g. a transistor relay. The input current required in order to control the operation of the transistor relay 106c may be low compared to the current required to control the operation of the electro-mechanical relays 106a, 106b and, hence, the processor module 104b may be directly coupled to the transistor relay 106c, as shown in FIG. 2b, and may directly control the operation of the relay.

In an alternative arrangement, the relay driver module 104c may control the operation of each of the relays regardless of the type of relays provided. In a further alternative arrangement, the processor module 104b may be configured to provided sufficient current to control, e.g. directly control, the operation of the relays 106a-c regardless of the type of relay. In this arrangement, the relay driver module 104c may not be provided.

With reference to FIG. 2a, the relay control box assembly 100 may comprise a first housing 108a, the controller 104, and the one or more relays 106a-c provided within the first housing 108a. Alternatively, as shown in FIG. 2b, the relay control box assembly 100 may further comprise a second housing 108b, and one or more of the relays 106a-c may be provided within the second housing 108b.

In an alternative arrangement (not shown), one or more modules of the controller 104 may be provided within the second housing 108b.

As shown in FIGS. 2A and 2B, a circuit board 110 may optionally be provided within the first and/or second housings 108a, 108b of the relay control box assembly 100. The relays 106a-106c may be coupled to the circuit board 110. The relays 106a-106c may be communicatively coupled to the controller 104 via the circuit board. The relay control box assembly 100 may further comprise a relay plug (not shown), which may be coupled to the circuit board. The relay plug may be configured to allow an electromechanical relay to be coupled to the circuit board 110. The circuit board 110 may be configured to allow both transistor relays and electromechanical relays to be coupled to the circuit board 110. In other words, the relays 106a-106c may be coupled to the circuit board 110 regardless of the type of relay provided.

In some arrangements (not shown), the controller 104 may be coupled to, e.g. mounted on, the circuit board 110. Alternatively, the controller 104 may be coupled to a further circuit board.

As described above, in the arrangement shown in FIG. 1, each of the relays 12a, 12b is controlled via different signal wires 18a, 18b, 20a, 20b, and the relay control box assembly 12 is configured to facilitate connections between each of the signal wires and the corresponding relay 12a, 12b. In contrast to this, by providing the relay control box assembly 100 depicted in FIGS. 2a and 2b, each of the relays may be controlled via the data bus 10 through the connection between the data bus 10 and the input 102 of the relay control box assembly 100. The data bus 10 and/or the ECUs 6, 8a, 8b may be configured to allow any number of relays to be controlled via the data bus 10. The number of wires provided in the electrical system 200, to control the operation of the relay control box assembly 100, e.g. the relays provided within the relay control box assembly, may be reduced. Furthermore, the number of connections at the input 102 of the relay control box assembly may be independent of the number of relays 106a-c provided in the relay control box assembly 100.

As shown in FIGS. 2A and 2B, the relay control box assembly 100, e.g. the first or second housing 108a, 108b of the relay control box assembly 100, may define a housing space 108c configured to allow one or more additional relays (not shown) to be provided within the housing. The relay control box assembly 100 may be configured such that the additional relays may comprise electromechanical relays, transistor relays or any combination thereof.

As described above, the relays 106a-106c may be mounted on the circuit board 110 provided within the first or second housing 108a, 108b. The circuit board 110 may further define a circuit board space 110a configured to allow one or more relays to be mounted on the circuit board 110 at the circuit board space 110a. The circuit board space 110a may be configured such that each of the additional relays can be either an electromechanical relay or transistor relay. The circuit board space 110a may be provided adjacent to the housing space 108c such that additional relays mounted to the circuit board may be housed within the housing space 108c.

The processor module 104b, and/or the relay driver module 104c, may be configured to couple to the additional relays, and control the operation of the additional relays according to the multiplex control signals received via the data bus 10, in the same way as described above, in relation to the relays 106a-c. Hence, when one or more additional relays are provided in the relay control box assembly 100, the additional relays may be controlled by one or more of the ECUs 6, 8a, 8b without additional signal wires being provided between the relevant ECUs and the relay control box assembly 100.

With reference to FIG. 4, a method 400 of upgrading a relay control box assembly, according to arrangements of the present disclosure, comprises a first step 402, in which an additional relay is provided. In a second step 404, the additional relay is communicatively coupled to the controller 104. The method 400 may further comprise a third step 406, in which the controller 104 is reconfigured to control the operation of the one or more additional relays, according to the multiplexed control signals, e.g. received via the data bus 10.

One or more of the ECUs provided in the electrical system 200 may be reconfigured, e.g. may be provided with updated software, to transmit multiplexed control signals to control the operation of the additional relays via the data bus 10.

By using the method 400, the electrical system 200 of the vehicle may be upgraded to include additional relay controlled devices, or systems, without requiring hardware changes to be made to the relay control box assembly 100 beyond the inclusion of the one or more additional relays.

As described above, when the vehicle is provided with the electrical system 2 depicted in FIG. 1, the process of upgrading the electrical system may require hardware changes to the relay control box assembly 12, and additional wiring to be installed in the vehicle. Additionally, if it is desirable to reconfigure the ECUs such that different ones of the ECUs control different ones of the relays 12a, 12b, it may also be necessary to provide additional wiring within the vehicle. Changing relay control to a different ECU may also require a hardware and/or software change to one or more of the ECUs.

Hence, when upgrades are required to the electrical system 2, or if it is desirable to reconfigure one or more of the ECUs 6, 8a, 8b, e.g. to control different ones of the first and second relays 12a, 12b, it may be desirable to retrofit the electrical system 2 with a relay control box assembly 100 according to arrangements of the present disclosure. In some cases, this may reduce the level of hardware changes and/or rewiring required on the vehicle, and may allow future upgrades or reconfiguration to be performed without hardware, or wiring changes being required.

As mentioned above, the relay control box assembly 12 may comprise ECU specific wiring or connections to allow a particular ECU to control the operation of a particular relay. This may lead to additional hardware changes when reconfiguring one or more of the ECUs 6, 8a, 8b, e.g. to control different ones of the first and second relays 12a, 12b. Furthermore, due to the ECU specific wiring, the relay control box 12 may be restricted to use on a particular vehicle comprising the particular ECUs that the relays control box assembly 12 has been configured. In contrast to this, the relay control box assembly 100 may not comprise ECU specific wiring, and, hence, the relay control box assembly 100 may be provided on any vehicle configured to control the relays 106a-c through control signals transmitted via the data bus 10.

With reference to FIG. 5, a method 500 of retrofitting a motor vehicle relay control box assembly comprises a first step 502, which a relay control box assembly 100 according to arrangements of the present disclosure is provided. The method may further comprise a second step 504, which the relay control box assembly 100 is coupled to a data bus 10 of the vehicle, e.g. at an input 102 of the relay control box assembly 100. The data bus 10 may be coupled to one or more ECUs 6, 8a, 8b of the vehicle.

The ECUs may have previously been configured to transmit control signals to the relay control box assembly via the signal wires 18a, 18b, 20a, 20b depicted in FIG. 1. Hence, the method may further comprise a third step 506, which one or more of the ECUs 6, 8a, 8b are reconfigured to transmit control signals to one or more of the relays via the data bus 10.

It will be appreciated by those skilled in the art that, although the invention has been described by way of example, with reference to one or more exemplary examples, it is not limited to the disclosed examples, and that alternative examples could be constructed without departing from the scope of the invention as defined by the appended claims.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. An electrical system for a motor vehicle comprising:
a control unit configured to control operation of one or more systems;
a multiplexed data bus, communicatively coupled to the control unit, configured to carry multiplexed control signals to and from the control unit; and
a relay control box assembly having a housing defining a housing space, wherein a controller and one or more relays are provided, being configured to receive one or more additional relays, and
the controller, communicatively coupled to the multiplexed data bus, being configured to:
decode the multiplexed control signals from the control unit to generate one or more decoded control signals; and
control operation of the one or more relays according to the decoded control signal.

2. The electrical system of claim 1 further comprising a relay driver module, in the relay control box assembly, configured to drive the one or more relays according to the decoded control signal.

3. The electrical system of claim 2 further comprising a processor module, in the relay control box assembly, configured to receive decoded control signals, and generate one or more relay control signals.

4. The electrical system of claim 3, wherein the processor module is communicatively coupled to the relay driver module, and the relay driver module is configured to drive the one or more relays according to the relay control signals.

5. The electrical system of claim 2 further comprising a decoder module, in the relay control box assembly, being configured to decode the multiplexed control signal.

6. The electrical system of claim 2 further comprising a circuit board, in the relay control box assembly, wherein the one or more relays are mounted on the circuit board.

7. The electrical system of claim 6, wherein the circuit board defines a circuit board space configured to allow one or more additional relays to be mounted on the circuit board.

8. The electrical system of claim 7, wherein the circuit board space is configured such that each of the additional relays can be either an electromechanical relay, or a transistor relay.

9. The electrical system of claim 1, wherein at least one of the relays is an electromechanical relay.

10. The electrical system of claim 1, wherein at least one of the relays is a transistor relay.

11. The electrical system of claim 1 further comprising one or more additional control units, wherein the additional control units are communicatively coupled to the multiplexed data bus, and wherein the controller is configured to receive multiplexed control signals from the additional control units.

12. A vehicle relay control box comprising:
an input configured to receive a multiplexed signal from a control unit;
a controller configured to decode the multiplexed signal;
a relay, operatively controlled according to the multiplexed signal; and
a housing, in which the controller and the relay are provided, defining a space configured to receive an additional relay.

13. The vehicle relay control box of claim 12 further comprising a circuit board, wherein the relay is mounted to the circuit board.

14. The vehicle relay control box of claim 13, wherein the circuit board defines a board space configured to receive the additional relay such that the additional relay is mounted on the circuit board.

15. A method of retrofitting a vehicle relay control box comprising:
providing a relay control assembly having:
a controller, communicatively coupled to an input, configured to decode multiplexed signals received at the input;
one or more relays communicatively coupled to the controller, operatively controllable according to the multiplexed signals; and
a housing, in which the controller and the one or more relays are provided, defining a space configured to receive one or more additional relays; and
coupling the input to a multiplexed data bus being communicatively coupled to one or more control units.

16. The method of claim 15 further comprising reconfiguring one or more of the one or more control units to transmit signals to the relay control assembly via the multiplexed data bus.

17. The method of claim 15 further comprising reconfiguring the controller to control operation of the one or more additional relays according to the multiplexed signals.

18. The method of claim 17 further comprising reconfiguring one or more of the one or more control units to transmit multiplexed signals via the multiplexed data bus to control operation of the additional relays.
